(19) United States
(12) Patent Application Publication
(10) Pub. No.: US 2012/0181583 A1
(43) Pub. Date: Jul. 19, 2012

(54) JUNCTION FIELD EFFECT TRANSISTOR AND MANUFACTURING METHOD THEREOF

(76) Inventor: Jae Hyun YOO, Seoul (KR)

(21) Appl. No.: 13/223,421

(22) Filed: Sep. 1, 2011

(30) Foreign Application Priority Data
Jan. 14, 2011 (KR) 10-2011-0004115

(51) Int. Cl. H01L 29/772; H01L 21/336

(52) U.S. Cl. 257/256; 438/186; 257/E29.242; 257/E21.409

(57) ABSTRACT

A junction field effect transistor includes a lower P-type substrate layer of a semiconductor substrate; an N-type channel layer which may be formed on and/or over the P-type substrate layer within an active area; an upper P-type diffusion layer which may be formed on and/or over the N-type channel layer at a prescribed depth over the entire active area; an additional P-type diffusion layer which may be formed in a ripple pattern in the upper P-type diffusion layer; a gate electrode which may be formed on and/or over the upper P-type diffusion layer; and a source electrode and a drain electrode which may be formed on and/or over both sides of the upper P-type diffusion layer within the active area on the semiconductor substrate. The additional P-type diffusion layer in the ripple pattern may be formed of a plurality of P-type diffusion layers which are formed to be separated from each other in the upper P-type diffusion layer.

The present application claims priority under 35 U.S.C. §119 to Korean Patent Application No. 10-2011-0004115 (filed on Jan. 14, 2011), which is hereby incorporated by reference in its entirety.

### BACKGROUND

In general, a junction field effect transistor refers to a transistor in which a current path is controlled by using an insulated gate through a PN junction.

In the junction field effect transistor, a voltage is applied to the gate to control an amount of current flowing through the drain and the source. When operating in a saturation region, the junction field effect transistor simply serves as an electrical switch. Meanwhile, when operating in an ohmic region, the junction field effect transistor serves as a voltage controlled variable resistor.

Since the junction field effect transistor has a linear current amplification property and low noise, it is usually applied in an amplification circuit of an acoustic sensor having excellent sensitivity, an amplification circuit having excellent linearity, an amplification circuit for input measurement, and the like.

FIG. 1 is a plane view illustrating a conventional junction field effect transistor. The junction field effect transistor includes a lower P-type diffusion layer 206, an upper P-type diffusion layer 214, and an active area 100.

FIGS. 2A to 2D are process views illustrating a method of manufacturing the conventional junction field effect transistor. Hereinafter, a method of manufacturing a junction field effect transistor will be described with reference to FIGS. 2A to 2D.

First, as illustrated in FIG. 2A, a P-type impurity 204, such as boron, is ion-implanted into a P-type substrate layer 200 by using a photoresist mask 202, which is patterned in an active area of a junction field effect transistor on a semiconductor substrate, to form a lower P-type diffusion layer 206.

Next, as illustrated in FIG. 2B, an N-type epitaxial layer is grown over the entire surface of the semiconductor substrate with the formed lower P-type diffusion layer 206, to form an N-type channel layer 208. Thereafter, in order to form an upper P-type diffusion layer, a P-type impurity 212, such as boron, is ion-implanted into an upper portion of the N-type channel layer 208 by using a patterned photoresist mask 210. Thus, an upper P-type diffusion layer 214 is formed.

Thereafter, as illustrated in FIG. 2C, a photoresist mask 216 for forming an additional P-type diffusion layer 220 is formed on and/or over the semiconductor substrate with the upper P-type diffusion layer 214 formed thereon. Then, a P-type impurity 218, such as boron, is ion-implanted into the upper P-type diffusion layer 214 by using the photoresist mask 216 to form an additional P-type diffusion layer 220.

As illustrated in FIG. 2D, after the additional P-type diffusion layer 220 is formed on the upper P-type diffusion layer 214, a gate electrode 222, a drain electrode 224, and a source electrode 226 are formed in the active area on the semiconductor substrate. Thus, a junction field effect transistor is formed.

However, it has not been possible to secure a sufficient distance ‘d’ between the lower P-type diffusion layer and the additional upper P-type diffusion layer which determines pinch-off, making it difficult to control pinch-off of the junction field effect transistor.

### SUMMARY

Embodiments relate to a junction field effect transistor and a manufacturing method thereof in which a P-type diffusion layer formed in an active area of a junction field effect transistor on a semiconductor substrate is formed in a ripple pattern in which two or more P-type diffusion layers are separated from each other, thereby securing a sufficient margin for a channel layer of a junction field effect transistor to facilitate pinch-off control.

Embodiments relate to a junction field effect transistor. In particular, embodiments relate to a junction field effect transistor and a manufacturing method thereof in which a P-type diffusion layer formed in the active area of the junction field effect transistor on a semiconductor substrate is formed in a ripple pattern, i.e., the P-type diffusion layer using two or more P-type diffusion layers separated from each other, thereby securing a sufficient margin for a channel layer of a junction field effect transistor to facilitate pinch-off voltage control.

In accordance with embodiments, a junction field effect transistor may include at least one of the following: a lower P-type substrate layer of a semiconductor substrate; an N-type channel layer which is formed on and/or over the P-type substrate layer within an active area; an upper P-type diffusion layer which is formed on and/or over the N-type channel layer at a prescribed depth over the entire active area; an additional P-type diffusion layer which is formed in a ripple pattern in the upper P-type diffusion layer; a gate electrode which is formed on and/or over the upper P-type diffusion layer; and a source electrode and a drain electrode which are formed on and/or over both sides of the upper P-type diffusion layer within the active area on the semiconductor substrate.

The additional P-type diffusion layer in the ripple pattern may be formed of a plurality of P-type diffusion layers which are formed to be separated from each other in the upper P-type diffusion layer.

The N-type channel layer may be formed by growing an N-type epitaxial layer on the P-type substrate layer.

In accordance with embodiments, a junction field effect transistor may include at least one of the following: a lower P-type diffusion layer which is formed in a ripple pattern at a lower portion of an active area of the transistor on and/or over a semiconductor substrate; an N-type channel layer which is formed on and/or over the lower P-type diffusion layer within the active area; an upper P-type diffusion layer which is formed on and/or over the N-type channel layer at a prescribed depth within the active area; an additional P-type diffusion layer which is formed in a ripple pattern in the upper P-type diffusion layer; a gate electrode which is formed on and/or over the upper P-type diffusion layer; and a source electrode and a drain electrode which are formed on and/or over both sides of the upper P-type diffusion layer within the active area on the semiconductor substrate.

The N-type channel layer may be formed by growing an N-type epitaxial layer on and/or over the semiconductor substrate having the lower P-type diffusion layer formed thereon.

The lower P-type diffusion layer may be formed of a plurality of P-type diffusion layers formed to be separated from each other on and/or over the semiconductor substrate within the active area.

The additional P-type diffusion layer may be formed of two or more P-type diffusion layers which are separately formed from each other in the upper P-type diffusion layer.

The P-type diffusion layers forming the lower P-type diffusion layer and the P-type diffusion layers forming the additional P-type diffusion layer may be located alternately.

Each of the P-type diffusion layers forming the lower P-type diffusion layer and those forming the additional P-type diffusion layer may be formed to have a predetermined width at a predetermined depth in a Y-axis direction on and/or over the semiconductor substrate and may be formed discontinuously at regular intervals.

The P-type diffusion layers forming the lower P-type diffusion layer and those forming the additional P-type diffusion layer may be located alternately.

The lower P-type diffusion layer may be formed by ion-implanting a P-type impurity into a predetermined area of the semiconductor substrate within the active area.

The additional P-type diffusion layer may be formed by ion-implanting a P-type impurity into a predetermined area of the upper P-type diffusion layer.

In accordance with embodiments, a method of manufacturing a junction field effect transistor may include at least one of the following: forming an N-type channel layer by growing an epitaxial layer on and/or over a substrate layer of a semiconductor substrate; forming an upper P-type diffusion layer at a prescribed depth through ion implantation into an active area of the N-type channel layer; forming an additional P-type diffusion layer in a ripple pattern through ion implantation into the upper P-type diffusion layer; forming a gate electrode on and/or over the upper P-type diffusion layer; and forming a source electrode and a drain electrode on and/or over both sides of the upper P-type diffusion layer within the active area on the semiconductor substrate.

Further, the forming the additional P-type diffusion layer in the ripple pattern may include at least one of the following: forming a mask having patterns opened at regular intervals on and/or over the upper P-type diffusion layer, and carrying out ion implantation into the upper P-type diffusion layer by using the mask to form a plurality of P-type diffusion layers separated from each other.

In accordance with embodiments, a method of manufacturing a junction field effect transistor may include at least one of the following: forming a lower P-type diffusion layer in a ripple pattern through ion implantation into an active area on a semiconductor substrate; forming an N-type channel layer by growing an epitaxial layer on and/or over the lower P-type diffusion layer; forming an upper P-type diffusion layer at a prescribed depth through ion implantation into the active area of the N-type channel layer; forming an additional P-type diffusion layer in a ripple pattern through ion implantation into the N-type channel layer; forming a gate electrode on and/or over the additional P-type diffusion layer within the active area; and forming a source electrode and a drain electrode in the active area.

Further, the forming the lower P-type diffusion layer in a ripple pattern may include at least one of the following: forming a mask having patterns opened at regular intervals at a lower portion of the active area on the semiconductor substrate, and carrying out ion implantation into the semiconductor substrate by using the mask to form a plurality of P-type diffusion layers separated from each other.

Further, the forming the additional P-type diffusion layer in a ripple pattern may include at least one of the following: forming a mask having a pattern opened at regular intervals on and/or over the upper P-type diffusion layer, and carrying out ion implantation into the upper P-type diffusion layer by using the mask to form a plurality of P-type diffusion layers separated from each other.

The P-type diffusion layers forming the lower P-type diffusion layer and those forming the additional P-type diffusion layer may be located alternately.

Each of the P-type diffusion layers forming the lower P-type diffusion layer and the additional P-type diffusion layer may be formed to have a predetermined width at a predetermined depth in a Y-axis direction on and/or over the semiconductor substrate and be formed discontinuously at regular intervals.

Further, the P-type diffusion layers forming the lower P-type diffusion layer and the additional P-type diffusion layer may be located alternately.

In accordance with embodiments, the P-type diffusion layer which is formed in the active area of the junction field effect transistor on and/or over the semiconductor substrate is formed in a ripple pattern using two or more P-type diffusion layers separated from each other, thereby securing a sufficient margin for the channel layer of the junction field effect transistor to facilitate pinch-off control.

In accordance with embodiments, in forming the P-type diffusion layer of the junction field effect transistor in a ripple pattern, it is not necessary to provide an additional mask process for generating each layer in order of generating the P-type diffusion layers, and the same mask as the existing process may be used. That is, only the layout of a mask process for a P type is changed and applied to the gate area of the junction field effect transistor, making it possible to form the P-type diffusion layer in a ripple pattern without an additional mask process. Therefore, embodiments can be easily applied to a manufacturing process of a junction field effect transistor.

### DRAWINGS

The above and other features of the present invention will become more apparent from the following description of embodiments given in conjunction with the accompanying drawings, in which:

FIG. 1 is a plane view illustrating a conventional junction field effect transistor.

FIGS. 2A to 2D are process views illustrating a method of manufacturing the conventional junction field effect transistor.

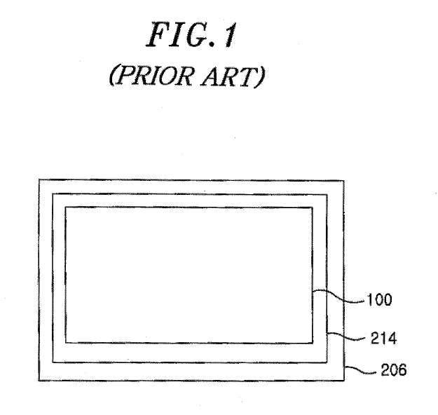

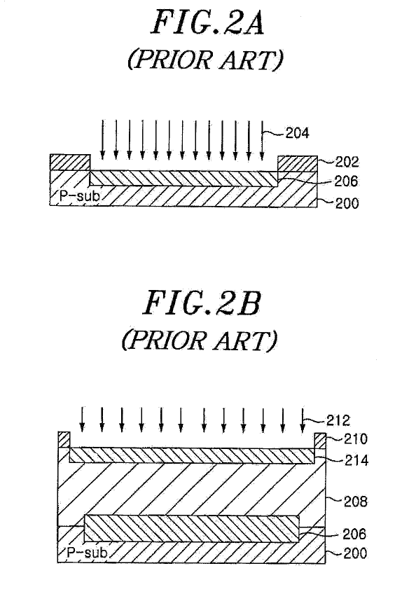

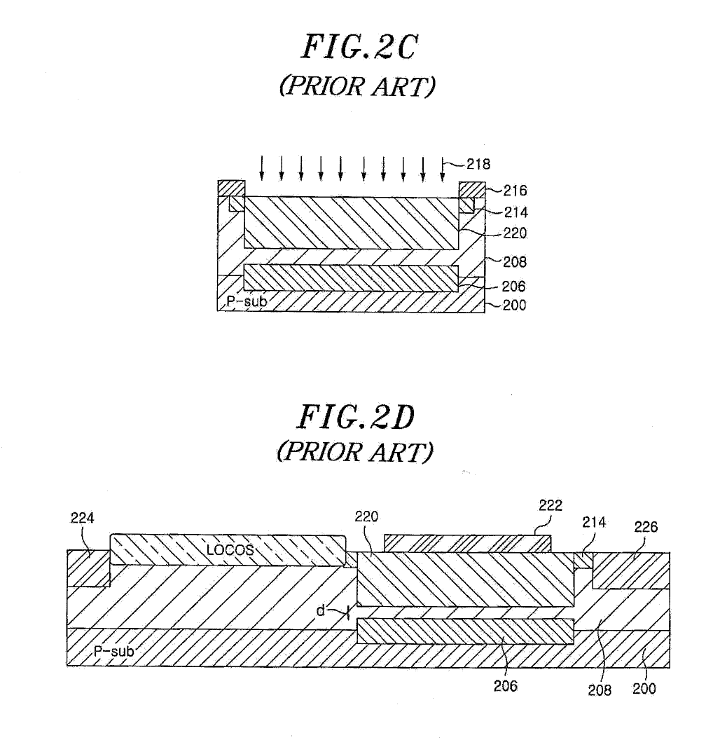

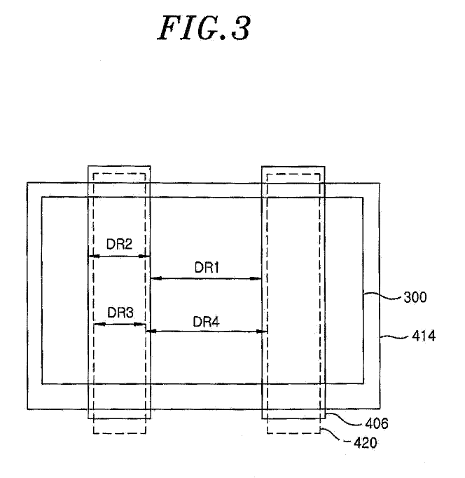

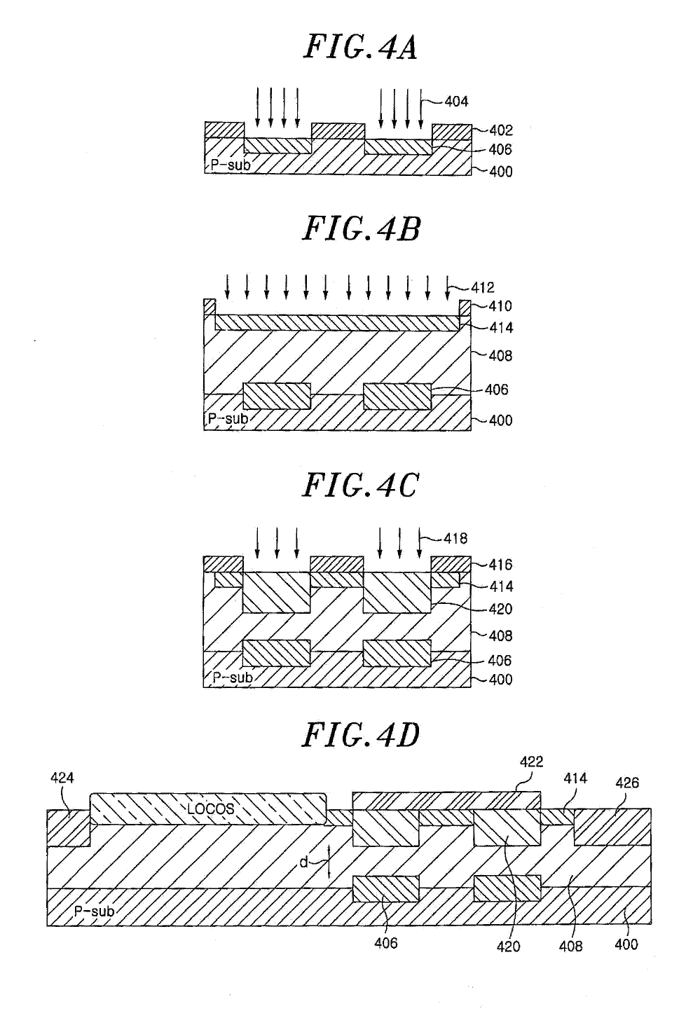

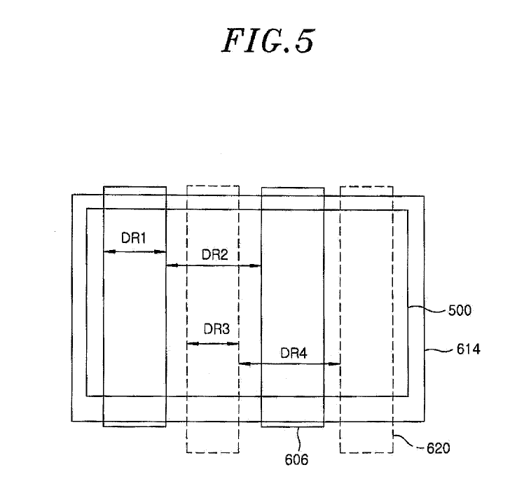

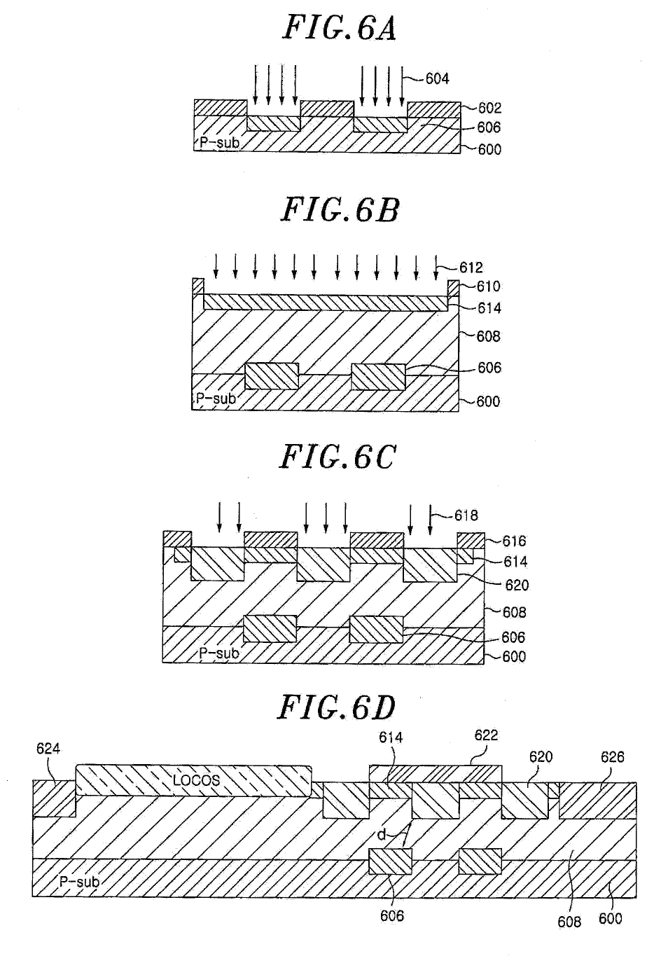

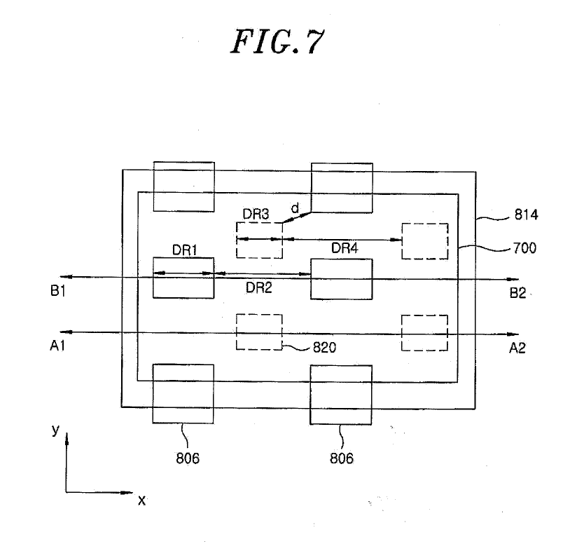

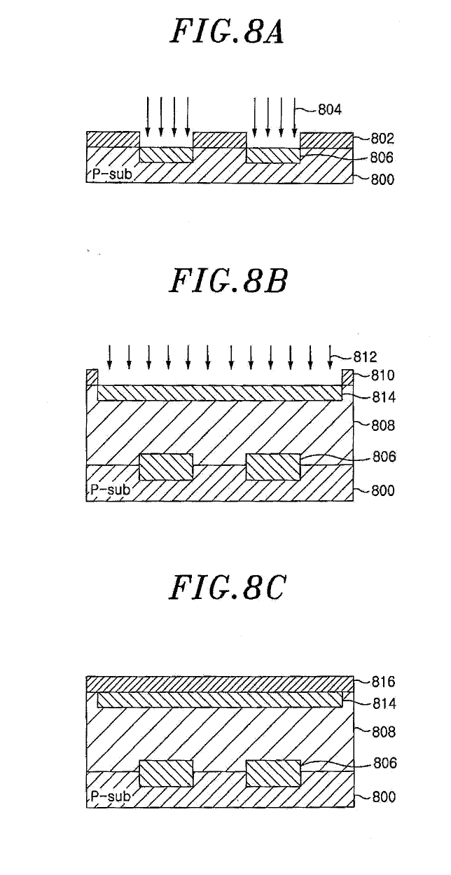

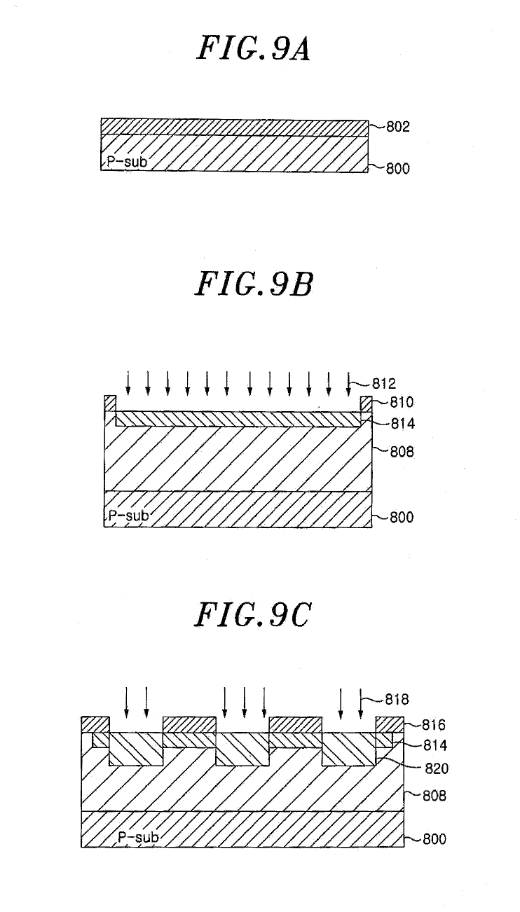

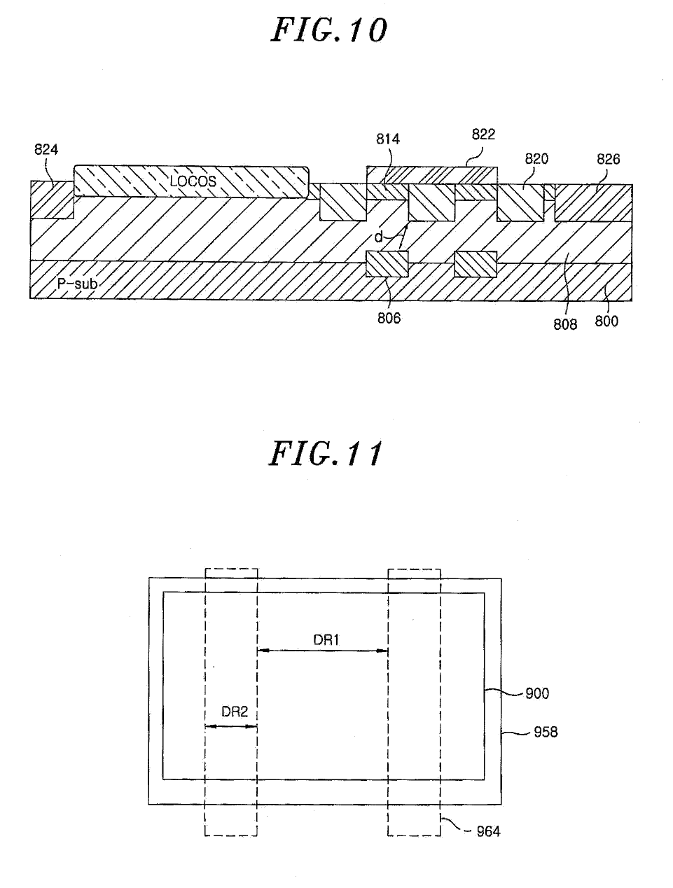

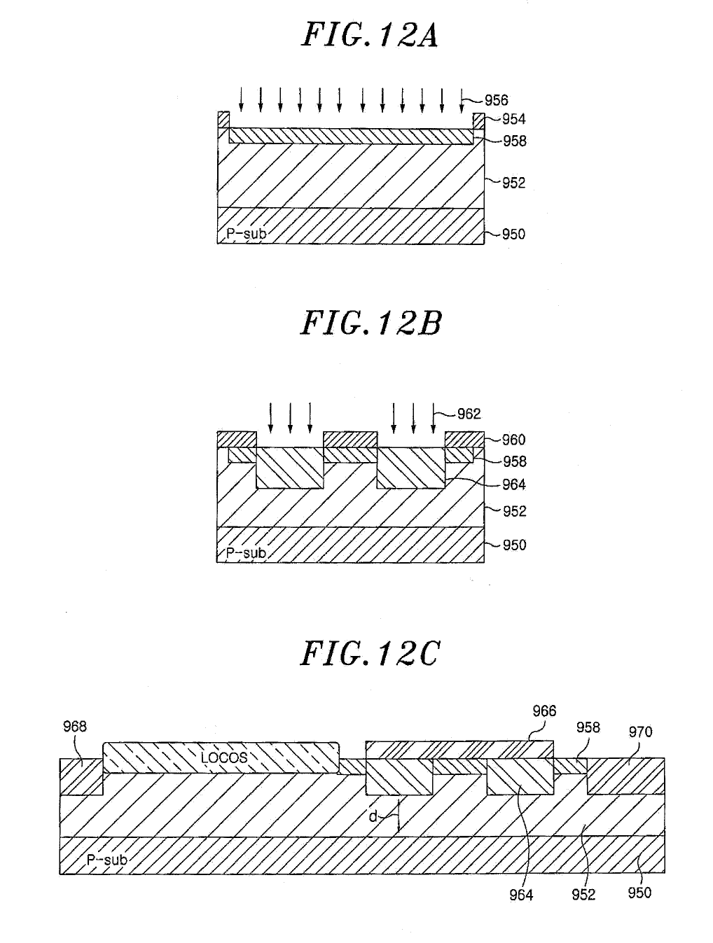

Example FIG. 3 is a plane view illustrating a junction field effect transistor, in which additional and lower P-type diffusion layers in a ripple pattern are correspondingly arranged, in accordance with embodiments.

Example FIGS. 4A to 4D are process views illustrating a manufacturing method of the junction field effect transistor illustrated in FIG. 3.

Example FIG. 5 is a plane view illustrating a junction field effect transistor, in which additional and lower P-type diffusion layers in a ripple pattern are alternately arranged, in accordance with embodiments.

Example FIGS. 6A to 6D are process views illustrating a manufacturing method of the junction field effect transistor illustrated in FIG. 5.

Example FIG. 7 is a plane view illustrating a junction field effect transistor, in which additional and lower P-type diffusion layers in a ripple pattern are alternately arranged in x-axis and y-axis directions, in accordance with embodiments.

Example FIGS. 8A to 8C are process views illustrating a manufacturing method of the junction field effect transistor taken along the line A1-A2 illustrated in FIG. 7.

Example FIGS. 9A to 9C are process views illustrating a manufacturing method of the junction field effect transistor taken along the line B1-B2 illustrated in FIG. 7.

Example FIG. 10 is a sectional view illustrating the junction field effect transistor illustrated in FIG. 7 with a gate electrode, a drain electrode, and a source electrode formed.

Example FIG. 11 is a plane view illustrating a junction field effect transistor, in which only an upper P-type diffusion layer is formed in a ripple pattern, in accordance with embodiments.

Example FIGS. 12A to 12C are process views illustrating a manufacturing method of the junction field effect transistor illustrated in FIG. 11.

### DESCRIPTION

Hereinafter, embodiments will be described in detail with reference to the accompanying drawings which form a part hereof.

Example FIG. 3 is a plane view illustrating a junction field effect transistor, in which additional and lower P-type diffusion layers in the structure of a junction field effect transistor are correspondingly arranged, in accordance with embodiments. In example FIG. 3, lower P-type diffusion layers 406, an upper P-type diffusion layer 414, additional P-type diffusion layer 420, and an active area 300 are illustrated.

Example FIGS. 4A to 4D are process views illustrating a manufacturing method of the junction field effect transistor in accordance with embodiments. Hereinafter, a manufacturing process of a junction field effect transistor in accordance with embodiments will be described in detail with reference to example FIGS. 4A to 4D.

First, as illustrated in example FIG. 4A, a P-type impurity 404, such as boron, may be ion-implanted into a P-type substrate layer 400 by using a photoresist mask 402 patterned in an active area of the junction field effect transistor on and/or over a semiconductor substrate to thereby form lower P-type diffusion layers 406.

The photoresist mask 402 may be patterned to be opened at a regular interval on and/or over the semiconductor substrate so that the lower P-type diffusion layers 406 can be separately formed from each other in the semiconductor substrate. Thus, the lower P-type diffusion layers 406 may have a ripple pattern.

As illustrated in example FIG. 4B, next an N-type channel layer 408 may then be formed by growing an N-type epitaxial layer on and/or over the entire surface of the semiconductor substrate having the lower P-type diffusion layers 406 formed in a ripple pattern. Thereafter, a P-type impurity 412, such as boron, may be ion-implanted into the N-type channel layer 408 by using a patterned photoresist mask 410 to form the upper P-type diffusion layer 414 at a prescribed depth.

As illustrated in example FIG. 4C, a photoresist mask 416 for forming additional P-type diffusion layers 420 may then be formed on and/or over the semiconductor substrate on and/or over which the upper P-type diffusion layer 414 has been formed. Thereafter, a P-type impurity 418, such as boron, may be ion-implanted into the upper P-type diffusion layer 414 by using the photoresist mask 416 to form the additional P-type diffusion layers 420.

Herein, substantially similar to the formation of the lower P-type diffusion layers 406, as illustrated in example FIG. 4C, the photoresist mask 416 may be patterned to be opened at a regular interval on and/or over the semiconductor substrate, so that the additional P-type diffusion layers 420 can be separately formed from each other in the upper P-type diffusion layer 414. Therefore, the additional P-type diffusion layers 420 also may have the ripple pattern substantially similar to the lower P-type diffusion layers 406.

As illustrated in example FIG. 4D, after forming the additional P-type diffusion layers 420 in the upper P-type diffusion layer 414, a gate electrode 422, a drain electrode 424, and a source electrode 426 may then be formed on and/or over the semiconductor substrate to form a junction field effect transistor.

As described above, in embodiments, the lower P-type diffusion layers 406 and the additional P-type diffusion layers 420 in the upper P-type diffusion layer 414 may be formed in a ripple pattern in which a plurality of, e.g., two or more, P-type diffusion layers are separated from each other. Thus, it is possible to maximize the distance ‘d’ between the additional P-type diffusion layers 420 and the lower P-type diffusion layers 406, thereby facilitating pinch-off control of the junction field effect transistor.

At this time, the distance ‘d’ between the additional P-type diffusion layers 420 and the lower P-type diffusion layers 406 may be determined depending on components, such as a distance DR1 between the lower P-type diffusion layers 406, a width DR2 of each of the additional P-type diffusion layers 420, a width DR3 of each of the lower P-type diffusion layers 406, and a distance DR4 between the additional P-type diffusion layers 420. Thus, it may be possible to adjust the distance ‘d’ between the additional P-type diffusion layers 420 and the lower P-type diffusion layers 406 by controlling the dimensions of the components.

That is, by forming the P-type diffusion layers in the ripple pattern in which the plurality of P-type diffusion layers are separately formed from each other within the active area, the ion implantation depth of each P-type diffusion layer may be minimized compared to a case where a single P-type diffusion layer is formed within the active area, such that the distance ‘d’ between the additional P-type diffusion layers 420 and the lower P-type diffusion layers 406 is maximized, thereby facilitating pinch-off control. Therefore, it is possible to overcome the problem in that a sufficient distance between the lower P-type diffusion layer and the additional P-type diffusion in the junction field effect transistor of the related art may not be secured, and pinch-off control may not be easily carried out.

Example FIG. 5 is a plane view illustrating a junction field effect transistor, in which additional and lower P-type diffusion layers in the structure of a junction field effect transistor are alternately arranged in accordance with embodiments. In example FIG. 5, lower P-type diffusion layers 606, an upper P-type diffusion layer 614, additional P-type diffusion layers 620, and an active area 500 are illustrated.

Example FIGS. 6A to 6D are process views illustrating a method of manufacturing a junction field effect transistor in accordance with embodiments. Hereinafter, a manufacturing process of a junction field effect transistor according to embodiments will be described in more detail with reference to example FIGS. 6A to 6D.

As illustrated in example FIG. 6A, first a P-type impurity 604, such as boron, may be ion-implanted into a P-type substrate layer 600 by using a patterned photoresist mask 602 in the active area of a junction field effect transistor on and/or over a semiconductor substrate to thereby form lower P-type diffusion layers 606.

A photoresist mask 604 may be patterned to be opened at a regular interval on the semiconductor substrate so that the lower P-type diffusion layers 606 can be separately formed from each other in the semiconductor substrate. Thus, the lower P-type diffusion layers 606 may have a ripple pattern.

As illustrated in example FIG. 6B, next an N-type channel layer 608 may then be formed by growing an N-type epitaxial layer on and/or over the entire surface of the semiconductor substrate on which the lower P-type diffusion layers 606 have been formed. Thereafter, a P-type impurity 612, such as boron, may be ion-implanted into the N-type channel layer 608 by a patterned photoresist mask 610 to form the upper P-type diffusion layer 614 at a prescribed depth.

As illustrated in example FIG. 6C, thereafter a photoresist mask 618 for forming additional P-type diffusion layers 620 may be formed on and/or over the semiconductor substrate on and/or over which the upper P-type diffusion layer 614 has been formed. Thereafter, a P-type impurity 618, such as boron, may be ion-implanted into the upper P-type diffusion layer 614 by using the photoresist mask 618 to form the additional P-type diffusion layers 620.

Herein, substantially similar to the formation of the lower P-type diffusion layers 606 illustrated in example FIG. 6C, the photoresist mask 618 may be patterned to be opened at regular intervals on and/or over the semiconductor substrate so that the additional P-type diffusion layers 620 can be separately formed from each other in the upper P-type diffusion layer 614. Therefore, the additional P-type diffusion layers 620 may have the ripple pattern.

As illustrated in example FIG. 6D, after the additional P-type diffusion layers 620 are formed in the upper P-type diffusion layer 614, a gate electrode 622, a drain electrode 624, and a source electrode 626 may be formed on and/or over the semiconductor substrate to form a junction field effect transistor.

As described above, in embodiments, the lower P-type diffusion layers 606 and the additional P-type diffusion layers 620 in the upper P-type diffusion layer 614 may be formed in a ripple pattern in which a plurality of P-type diffusion layers are separately formed from each other, and the lower P-type diffusion layers 606 and the additional P-type diffusion layers 620 are alternately formed. Thus, the distance ‘d’ between the additional P-type diffusion layers 620 and the lower P-type diffusion layers 606 may be implemented diagonally, such that it may be possible to maximize the distance ‘d’, thereby further facilitating pinch-off control of the junction field effect transistor.

At this time, the distance ‘d’ between the additional P-type diffusion layers 620 and the lower P-type diffusion layers 606 may be determined depending on components, such as the width DR1 of each of the lower P-type diffusion layers 606, the distance DR2 between the lower P-type diffusion layers 606, the width DR3 of each of the additional P-type diffusion layers 620, and the distance DR4 between the additional P-type diffusion layers 620. Thus, it may be possible to adjust the distance ‘d’ between the additional P-type diffusion layers 620 and the lower P-type diffusion layers 606 by the dimensions of the components.

That is, since the P-type diffusion layers may be formed in the ripple patterns in which a plurality of P-type diffusion layers are separately formed from each other within the active area, and the lower P-type diffusion layers 606 and the additional P-type diffusion layers 620 are alternately formed, the distance ‘d’ between the additional P-type diffusion layers 620 and the lower P-type diffusion layers 606 may be maximized, thereby further facilitating pinch-off control. Therefore, it may be possible to overcome the problem in that a sufficient distance between the lower P-type diffusion layer and the upper P-type diffusion layer in the junction field effect transistor of the related art may not be secured, and pinch-off control may not be easily carried out.

Example FIG. 7 is a plane view illustrating a junction field effect transistor, in which upper and lower P-type diffusion layers in a ripple pattern in the structure of a junction field effect transistor may be alternately arranged in accordance with embodiments. In example FIG. 7, lower P-type diffusion layers 806, an upper P-type diffusion layer 814, additional P-type diffusion layers 820, and an active area 700 are illustrated.

Referring to example FIG. 7, unlike the structure of example FIG. 5 in which the additional P-type diffusion layers and the lower P-type diffusion layers may be alternately arranged in the x-axis direction only, FIG. 7 illustrates a structure made such that additional P-type diffusion layers 820 and lower P-type diffusion layers 806 may be alternately arranged in the y-axis direction as well. Thus, the distance between the lower P-type diffusion layers 806 and the additional P-type diffusion layers 820 is implemented diagonally in the x-axis and y-axis directions, such that the distance therebetween can be further maximized

Each of the lower P-type diffusion layers 806 and the additional P-type diffusion layers 820 may be formed to have a predetermined width at a predetermined depth in a Y-axis direction and may be formed discontinuously at regular intervals.

Example FIGS. 8A to 8C are process views illustrating a method of manufacturing a junction field effect transistor in accordance with embodiments, and in particular, they illustrate process views taken along line A1-A2 of example FIG. 7.

Example FIGS. 9A to 9C are process views illustrating a method of manufacturing a junction field effect transistor in accordance with embodiments, and in particular, they illustrate process views taken along line B1-B2 of example FIG. 7.

Hereinafter, a manufacturing process of a junction field effect transistor in accordance with embodiments of the invention will be described in detail with reference to example FIGS. 8A to 9C.

As illustrated in example FIG. 8A, initially, in forming lower P-type diffusion layers on and/or over a semiconductor substrate, a P-type impurity 804, such as boron, may be ion-implanted into a P-type substrate layer 800 by using a patterned photoresist mask 802 in the active area of a junction field effect transistor on and/or over the semiconductor substrate to form the lower P-type diffusion layers 806.

As further illustrated in example FIG. 8A, herein the photoresist mask 802 may be patterned to be opened at a regular interval on the semiconductor substrate, so that the lower P-type diffusion layers 806 can be separately formed from each other in the semiconductor substrate. Thus, the lower P-type diffusion layers 806 may have a ripple pattern.

As illustrated in example FIG. 8B, next an N-type channel layer 808 may then be formed by growing an N-type epitaxial layer on and/or over the entire surface of the semiconductor substrate on and/or over which the lower P-type diffusion layers 806 have been formed in the ripple pattern. Thereafter, a P-type impurity 812, such as boron, may be ion-implanted into the N-type channel layer 808 by using a patterned photoresist mask 810 to form the upper P-type diffusion layer 814 at a prescribed depth.

As illustrated in example FIG. 8C, thereafter a photoresist mask 816 for forming additional P-type diffusion layers 820 may be formed on and/or over the semiconductor substrate on and/or over which the upper P-type diffusion layer 814 has been formed. However, the photoresist mask 816 is not opened in the area of the sectional view taken along the line A1-A2. For this reason, ion implantation of a P-type impurity may be blocked so that the additional P-type diffusion layers 820 in the upper P-type diffusion layer 814 cannot be formed.

The manufacturing of the junction field effect transistor illustrated in example FIGS. 9A to 9C correspond to the process illustrated in example FIGS. 8A to 8C.

As illustrated in example FIG. 9A, since the photoresist mask 802 is not opened in the area of the sectional view taken along the line B1-B2, ion implantation of the P-type impurity 804 may be blocked in the ion-implantation of the P-type impurity, such as boron, for forming the lower P-type diffusion layers 806 described with reference to example FIG. 8A. Thus, in the area of the sectional view taken along the line B1-B2, no lower P-type diffusion layer 806 is formed in the semiconductor substrate.

As illustrated in example FIG. 9B, next an N-type channel layer 808 may then be formed by growing an N-type epitaxial layer on and/or over the entire surface of the semiconductor substrate on and/or over which no lower P-type diffusion layer 806 has been formed in the area of the sectional view taken along the line B1-B2. Thereafter, as in the process sectional view of example FIG. 8B, a P-type impurity 812, such as boron, may be ion-implanted into the N-type channel layer 808 to form the upper P-type diffusion layer 814 at a prescribed depth.

As illustrated in example FIG. 9C, thereafter a photoresist mask 816 may then be formed on and/or over the semiconductor substrate on and/or over which the upper P-type diffusion layer 814 has been formed. Then, a P-type impurity 818, such as boron, may be ion-implanted into the upper P-type diffusion layer 814 by using the photoresist mask 816 to form the additional P-type diffusion layers 820.

Herein, in forming the additional P-type diffusion layers 820 in the upper P-type diffusion layer 814, substantially similar to the formation of the lower P-type diffusion layers 806, as illustrated in example FIG. 9C, a photoresist mask 816 may be patterned to be opened at regular intervals on and/or over the semiconductor substrate so that the additional P-type diffusion layers 820 can be separately formed from each other in the upper P-type diffusion layer 814. Therefore, the additional P-type diffusion layers 820 may have the ripple pattern.

As described above, after the lower P-type diffusion layers 806 and the additional P-type diffusion layers 820 are alternately formed on and/or over the semiconductor substrate, a gate electrode 822, a drain electrode 824, and a source electrode 826 may be formed on and/or over the semiconductor substrate, thereby forming a junction field effect transistor having a structure illustrated in example FIG. 10.

As described above, in embodiments, the lower P-type diffusion layers 806 and the additional P-type diffusion layers 820 in the upper P-type diffusion layer 814 may be formed in the ripple pattern in which a plurality of P-type diffusion layers are separated from each other. Further, the lower P-type diffusion layers 806 and the additional P-type diffusion layers 820 may be alternately formed in the x-axis and y-axis directions. Therefore, the distance ‘d’ between the additional P-type diffusion layers 820 and the lower P-type diffusion layers 806 may be implemented diagonally, such that the distance ‘d’ can be maximized, thereby further facilitating pinch-off control of the junction field effect transistor.

Herein, the distance ‘d’ between the additional P-type diffusion layers 820 and the lower P-type diffusion layers 806 may be determined depending on components, such as the width DR1 of each of the lower P-type diffusion layers 806, the distance DR2 between the lower P-type diffusion layers 806, the width DR3 of each of the additional P-type diffusion layers 820, and the distance DR4 between the additional P-type diffusion layers 820. Thus, it may be possible to adjust the distance ‘d’ between the additional P-type diffusion layers 820 and the lower P-type diffusion layers 806 by controlling the dimensions of the components.

That is, since the P-type diffusion layers may be formed in the ripple pattern in which a plurality of P-type diffusion layers are separated from each other within the active area and the lower P-type diffusion layers 806 and the additional P-type diffusion layers 820 may be alternately formed in the x-axis and y-axis directions, the distance ‘d’ between the additional P-type diffusion layers 820 and the lower P-type diffusion layers 806 may be maximized, thereby further facilitating pinch-off control. Therefore, it may be possible to overcome the problem in that a sufficient distance between the lower P-type diffusion layer and the upper P-type diffusion layer in the junction field effect transistor may not be secured, and pinch-off control may not be easily carried out.

Example FIG. 11 is a plane view of a junction field effect transistor, in which only an upper P-type diffusion layer in the structure of a junction field effect transistor is formed in a ripple form in accordance with embodiments. In example FIG. 11, an upper P-type diffusion layer 958, additional P-type diffusion layers 964, and an active area 900 are illustrated.

Example FIGS. 12A to 12C are process views illustrating a method of manufacturing a junction field effect transistor in accordance with embodiments.

Hereinafter, a manufacturing process of a junction field effect transistor according to embodiments will be described in detail with reference to example FIGS. 12A to 12C.

As illustrated in example FIG. 12A, initially an N-type channel layer 952 may be formed by growing an N-type epitaxial layer on and/or over the P-type substrate layer 950 on and/or over a semiconductor substrate. Thereafter, a P-type impurity 956, such as boron, may be ion-implanted into the N-type channel layer 952 by using a photoresist mask 954 patterned to form an upper P-type diffusion layer 958.

As illustrated in example FIG. 12B, next a photoresist mask 960 for forming additional P-type diffusion layers 964 may then be formed on and/or over the semiconductor substrate on and/or over which the upper P-type diffusion layer 958 has been formed. Thereafter, a P-type impurity 962, such as boron, may be ion-implanted into the upper P-type diffusion layer 958 by using the photoresist mask 960 to form the additional P-type diffusion layers 964. At this time, as further illustrated in example FIG. 12B, the photoresist mask 960 may be patterned to be opened at a regular interval on and/or over the semiconductor substrate, so that the additional P-type diffusion layers 964 may be formed in a ripple pattern to be separated from each other in the upper P-type diffusion layer 958.

As illustrated in example FIG. 12C, after the additional P-type diffusion layers 964 are formed in the upper P-type diffusion layer 958, a gate electrode 966, a drain electrode 968, and a source electrode 970 may then be formed on and/or over the semiconductor substrate to form a junction field effect transistor.

As described above, in embodiments, the additional P-type diffusion layers 964 may be formed in the ripple pattern in which a plurality of P-type diffusion layers are separated from each other in the upper P-type diffusion layer 958, such that it may be possible to maximize the distance ‘d’ between the additional P-type diffusion layers 964 and the P-type substrate layer 950, thereby further facilitating pinch-off control of the junction field effect transistor.

At this time, the distance ‘d’ between the additional P-type diffusion layers 964 and the P-type substrate layer 950 may be determined depending on components, such as the distance DR1 between the additional P-type diffusion layers 964 and the width DR2 of each of the additional P-type diffusion layers 964. Therefore, it may be possible to adjust the distance ‘d’ between the additional P-type diffusion layers 964 and the P-type substrate layer 950 by the dimensions of the components.

That is, in forming the additional P-type diffusion layers 964 in a ripple pattern in which a plurality of P-type diffusion layers are separated from each other within the active area, the ion implantation depth of each P-type diffusion layer may be minimized compared to a case where a single P-type diffusion layer is formed in the active area. Therefore, it may be possible to relatively extend the distance between the additional P-type diffusion layers 964 and the P-type substrate layer 950 of the semiconductor substrate, thereby facilitating pinch-off control. Therefore, it may be possible to overcome the problem in that a sufficient distance between the P-type substrate layer and the upper P-type diffusion layer in the junction field effect transistor of the related art may not be secured, and pinch-off control may not be easily carried out.

As described above, with the junction field effect transistor and the method of manufacturing the same in accordance with embodiments, the P-type diffusion layer which is formed in the active area of the junction field effect transistor on and/or over the semiconductor substrate may be formed in a ripple pattern in which two or more P-type diffusion layers are separated from each other, thereby securing a sufficient margin for the channel layer of the junction field effect transistor to facilitate pinch-off control.

In accordance with embodiments, in forming the P-type diffusion layer of the junction field effect transistor in a ripple pattern, it may not be necessary to provide an additional mask process for generating each layer in order of generating the P-type diffusion layers, and the same mask as the existing process may be used. That is, only the layout of a mask process for a P type may be changed and applied to the gate area of the junction field effect transistor, making it possible to form the P-type diffusion layer in a ripple pattern without an additional mask process. Therefore, embodiments can be easily applied to a manufacturing process of a junction field effect transistor.

Although embodiments have been described, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A junction field effect transistor comprising:
a semiconductor substrate having a lower P-type substrate layer;
an N-type channel layer formed over the lower P-type substrate layer in an active area of the junction field effect transistor;
a first P-type diffusion layer formed over the N-type channel layer and over an entire portion of the active area;
a second P-type diffusion layer formed in a ripple pattern in the first P-type diffusion layer;
a gate electrode formed over the first P-type diffusion layer;
a source electrode formed adjacent a first lateral side of the first P-type diffusion layer; and
a drain electrode formed adjacent a second lateral side of the first P-type diffusion layer.

2. The junction field effect transistor of claim 1, wherein the second P-type diffusion layer comprises a plurality of P-type diffusion layers that are spatially separated from each other in the first P-type diffusion layer.

3. The junction field effect transistor of claim 1, wherein the N-type channel layer is formed by growing an N-type epitaxial layer over the P-type substrate layer.

4. The junction field effect transistor of claim 1, wherein:
the first P-type diffusion layer is formed at a first predetermined depth; and
the second P-type diffusion layer is formed at a second predetermined depth which is greater than the first predetermined depth.

5. A junction field effect transistor comprising:
a lower P-type diffusion layer formed in a ripple pattern at a lower portion of an active area of a semiconductor substrate;
an N-type channel layer formed over the lower P-type diffusion layer;
a first upper P-type diffusion layer formed over the N-type channel layer;
a second upper P-type diffusion layer formed in a ripple pattern in the upper P-type diffusion layer;
a gate electrode formed over the first and second upper P-type diffusion layers;
a source electrode formed laterally to the first upper P-type diffusion layer; and
a drain electrode formed laterally to the first upper P-type diffusion layer.

6. The junction field effect transistor of claim 4, wherein:
the lower P-type diffusion layer comprises a plurality of lower P-type diffusion layers spatially separated from each other; and
the second upper P-type diffusion layer comprises a plurality of second upper P-type diffusion layers separated from each other.

7. The junction field effect transistor of claim 6, wherein the plurality of lower P-type diffusion layers are spatially located in an alternating pattern with respect to the plurality of second upper P-type diffusion layers.

8. The junction field effect transistor of claim 7, wherein each of the plurality of P-type diffusion layers and each of the second, upper P-type diffusion layers is formed:
having a predetermined width at a predetermined depth in a Y-axis direction of the semiconductor substrate; and
discontinuously at regular spatial intervals.

9. The junction field effect transistor of claim 6, wherein the plurality of lower P-type diffusion layers are located to correspond spatially with respect to the plurality of second upper P-type diffusion layers.

10. The junction field effect transistor of claim 4, wherein the lower P-type diffusion layer is formed by ion-implanting a P-type impurity into a predetermined area of the active area.

11. The junction field effect transistor of claim 4, wherein the second upper P-type diffusion layer is formed by ion-implanting a P-type impurity into a predetermined area of the first upper P-type diffusion layer.

12. The junction field effect transistor of claim 4, wherein:
the lower P-type diffusion layer is formed by ion-implanting a P-type impurity into a predetermined area of the active area; and
the second upper P-type diffusion layer is formed by ion-implanting a P-type impurity into a predetermined area of the first upper P-type diffusion layer.

13. A method of manufacturing a junction field effect transistor, the method comprising:
forming a lower P-type diffusion layer in into an active area of a semiconductor substrate;
forming an N-type channel layer over the lower P-type diffusion layer;
forming a first upper P-type diffusion layer by ion-implanting to a first predetermined depth a first substance into the N-type channel layer; and then
forming a second upper P-type diffusion layer in a ripple pattern by ion-implanting to a second predetermined depth a second substance into the first upper P-type diffusion layer,
wherein the first predetermined depth is less than the second predetermined depth.

14. The method of claim 13, wherein:
forming the lower P-type diffusion layer comprises forming a first mask having a pattern opened at regular spatial intervals at a lower portion of the semiconductor substrate, and then ion-implanting a P-type impurity into the semiconductor substrate using the mask to form a plurality of lower P-type diffusion layers that are spatially separated from each other; and
forming the second upper P-type diffusion layer comprises forming a mask having a pattern opened at regular spatial intervals over the first upper P-type diffusion layer, and then ion-implanting a P-type impurity into the first upper P-type diffusion layer using the mask to form a plurality of second upper P-type diffusion layers that are spatially separated from each other.

15. The method of claim 14, wherein the plurality of lower P-type diffusion layers are spatially located in an alternating pattern with respect to the plurality of second upper P-type diffusion layers.

16. The method of claim 14, wherein the plurality of lower P-type diffusion layers are located to correspond spatially with respect to the plurality of second upper P-type diffusion layers.

17. The method of claim 14, wherein each of the plurality of lower P-type diffusion layers and each of the plurality of second upper P-type diffusion layers is formed:
having a predetermined width at a predetermined depth in a Y-axis direction of the semiconductor substrate; and
discontinuously at regular intervals.

18. The method of claim 13, further comprising:
forming a gate electrode over the first upper P-type diffusion layer;
forming a source electrode laterally to the first upper P-type diffusion layer; and then
forming a drain electrode laterally to the first upper P-type diffusion layer at on another side thereof.

19. The method of claim 13, further comprising:
forming a gate electrode over the second upper P-type diffusion layer; and then
forming a source electrode laterally to the second upper P-type diffusion layer; and then
forming a drain electrode laterally to the second upper P-type diffusion layer at on another side thereof.

20. The method of claim 13, wherein forming the N-type channel layer comprises growing an N-type epitaxial layer over the lower P-type diffusion layer.
